(19) United States
(12) Patent Application Publication
(10) Pub. No.: US 2025/0062225 A1
(43) Pub. Date: Feb. 20, 2025

(54) TRENCH LINER FUSE

(71) Applicant: INTERNATIONAL BUSINESS MACHINES CORPORATION, Armonk, NY (US)

(72) Inventors: Ashim Dutta, Clifton Park, NY (US); Chih-Chao Yang, Glenmont, NY (US); Ailian Zhao, Slingerlands, NY (US); Wu-Chang Tsai, Albany, NY (US)

(21) Appl. No.: 18/451,870

(22) Filed: Aug. 18, 2023

(51) Int. Cl. H01L 23/525; H01L 23/528; H01L 23/532; H01L 23/62; H01L 21/768

(52) U.S. Cl. CPC H01L 23/5256; H01L 23/528; H01L 23/53209; H01L 23/62; H01L 21/76801; H01L 21/76843; H01L 21/76885

(57) ABSTRACT

A fuse structure including a first conductive line and a second conductive line, a first metal pillar extending vertically from a top surface of the first conductive line and a second metal pillar extending vertically from a top surface of the second conductive line, a conductive link electrically connecting a top surface of the first metal pillar with a top surface of the second metal pillar, where both the first conductive line and the second conductive line are a different material than both the first metal pillar and the second metal pillar, and where both the first metal pillar and the second metal pillar are a different metal than the conductive link.

### BACKGROUND

The present invention generally relates to semiconductor structures, and more particularly to a trench liner fuse structure.

Integrated circuit processing can be generally divided into front end of the line (FEOL), middle of the line (MOL) and back end of the line (BEOL) processes. The FEOL and MOL processing will generally form many layers of logical and functional devices. By way of example, the typical FEOL processes include wafer preparation, isolation, well formation, gate patterning, spacer, extension and source/drain implantation, silicide formation, and dual stress liner formation. The MOL is mainly gate contact formation. Layers of interconnections are formed above these logical and functional layers during the BEOL processing to complete the integrated circuit structure. As such, BEOL processing generally involves the formation of insulators and conductive wiring. The industry has typically used copper as the conductive metal for the interconnect structures most often using a dual damascene process to form a metal line/via interconnect structure.

A fuse is a structure that is normally “on” meaning that current is flowing, but once “programmed” it is “off” meaning that current does not flow. In a fuse, programming means applying a suitable voltage so that the fuse “blows” to create an open circuit or high resistance state. An antifuse is a structure that is normally “off” meaning that no current flows, but once “programmed” it is “on” meaning that current does flow. In an antifuse, programming means applying a suitable voltage to two electrodes and forming a conductive link between them to close the circuit.

In integrated circuitry memory devices, fuses and antifuses can be used for activating redundancy in memory chips and for programming functions and codes in logic chips. Specifically, dynamic random access memory (DRAM) and static random access memory (SRAM) may use fuses and antifuses for such purposes. In addition, fuses and antifuses can also be used to prevent decreased chip yield caused by random defects generated in the manufacturing process. Moreover, fuses and anti-fuses provide for future customization of a standardized chip design. For example, fuses and anti-fuses may provide for a variety of voltage options, packaging pin out options, or any other options desired by the manufacturer to be employed prior to the final processing. These customization possibilities make it easier to use one basic design for several different end products and help increase chip yield.

### SUMMARY

According to an embodiment of the present invention, a fuse structure is provided. The fuse structure may include a first conductive line and a second conductive line, a first metal pillar extending vertically from a top surface of the first conductive line and a second metal pillar extending vertically from a top surface of the second conductive line, a conductive link electrically connecting a top surface of the first metal pillar with a top surface of the second metal pillar, where both the first conductive line and the second conductive line are a different material than both the first metal pillar and the second metal pillar, and where both the first metal pillar and the second metal pillar are a different metal than the conductive link.

According to another embodiment of the present invention, a fuse structure is provided. The fuse structure may include a first metal line and a second metal line, a first metal pillar extending vertically from a top surface of the first metal line and a second metal pillar extending vertically from a top surface of the second metal line, a conductive link electrically connecting a top surface of the first metal pillar to a top surface of the second metal pillar, where both the first metal line and the second metal line are a different metal than both the first metal pillar and the second metal pillar, where both the first metal pillar and the second metal pillar are a different metal than the conductive link, and where the conductive link directly contacts a sidewall of the first metal pillar and a sidewall of the second metal pillar.

According to another embodiment of the present invention, a fuse structure is provided. The fuse structure may include a first metal via and a second metal via, a first metal pillar extending vertically from a top surface of the first metal via and a second metal pillar extending vertically from a top surface of the second metal via, wherein both the first metal via and the second metal via are a different metal than both the first metal pillar and the second metal pillar; and a conductive link electrically connecting the first metal pillar to the second metal pillar, where both the first metal pillar and the second metal pillar are a different metal than the conductive link, where the conductive link comprises a first cross-sectional dimension and a second cross-sectional dimension, where the first cross-sectional dimension is smaller than the second cross-sectional dimension, and wherein the first cross-sectional dimension is approximately located at a mid-point between the first metal pillar and the second metal pillar.

### BRIEF DESCRIPTION OF THE DRAWINGS

The following detailed description, given by way of example and not intended to limit the invention solely thereto, will best be appreciated in conjunction with the accompanying drawings, in which:

FIG. 1, illustrates a cross-sectional view of the semiconductor structure during an intermediate step of a method of fabricating an interconnect structure according to an exemplary embodiment;

FIG. 2, illustrates a cross-sectional view of the semiconductor structure after forming a conductive liner according to an exemplary embodiment;

FIG. 3, illustrates a cross-sectional view of the semiconductor structure after forming metal pillars according to an exemplary embodiment;

FIG. 4, illustrates a cross-sectional view of the semiconductor structure after forming a third dielectric layer according to an exemplary embodiment;

FIG. 5, illustrates a cross-sectional view of the semiconductor structure after forming a conductive link according to an exemplary embodiment;

FIG. 6, illustrates a cross-sectional view of the semiconductor structure after forming a fourth dielectric layer according to an exemplary embodiment;

FIG. 7, illustrates a cross-sectional view of the semiconductor structure during an intermediate step of a method of fabricating an interconnect structure according to another exemplary embodiment;

FIG. 8, illustrates a cross-sectional view of the semiconductor structure after forming a conductive liner according to an exemplary embodiment;

FIG. 9, illustrates a cross-sectional view of the semiconductor structure after forming a third dielectric layer according to an exemplary embodiment;

FIG. 10, illustrates a cross-sectional view of the semiconductor structure after forming a fourth dielectric layer according to an exemplary embodiment;

FIG. 11, illustrates a cross-sectional view of the semiconductor structure after forming openings according to an exemplary embodiment;

FIG. 12, illustrates a cross-sectional view of the semiconductor structure after forming conductive link according to an exemplary embodiment;

FIG. 13, illustrates a cross-sectional view of the semiconductor structure after forming a fifth dielectric layer according to an exemplary embodiment;

FIG. 14, illustrates a cross-sectional view of the semiconductor structure during an intermediate step of a method of fabricating an interconnect structure according to another exemplary embodiment;

FIG. 15, illustrates a cross-sectional view of the semiconductor structure after forming a conductive liner according to an exemplary embodiment;

FIG. 16, illustrates a cross-sectional view of the semiconductor structure after forming metal pillars and depositing a third dielectric layer according to an exemplary embodiment;

FIG. 17, illustrates a cross-sectional view of the semiconductor structure after forming a fourth dielectric layer according to an exemplary embodiment;

FIG. 18, illustrates a cross-sectional view of the semiconductor structure after forming openings according to an exemplary embodiment;

FIG. 19, illustrates a cross-sectional view of the semiconductor structure after forming a conductive link according to an exemplary embodiment; and

FIG. 20, illustrates a cross-sectional view of the semiconductor structure after forming a fifth dielectric layer according to an exemplary embodiment;

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Fuses become difficult to fabricate when interconnect dimensions scale down. Such fuse features are difficult to fabricate as the spacing between the metal wires becomes sub-15 nm due to the limitation of printing small features using lithography. Additionally, conventional fuse structures are typically relatively bulky and take up a valuable space in an integrated circuit design. Further, bulky fuse structures reduce the amount of available space for more important interconnect structures, for example, metal wires, and other circuit components in the circuit.

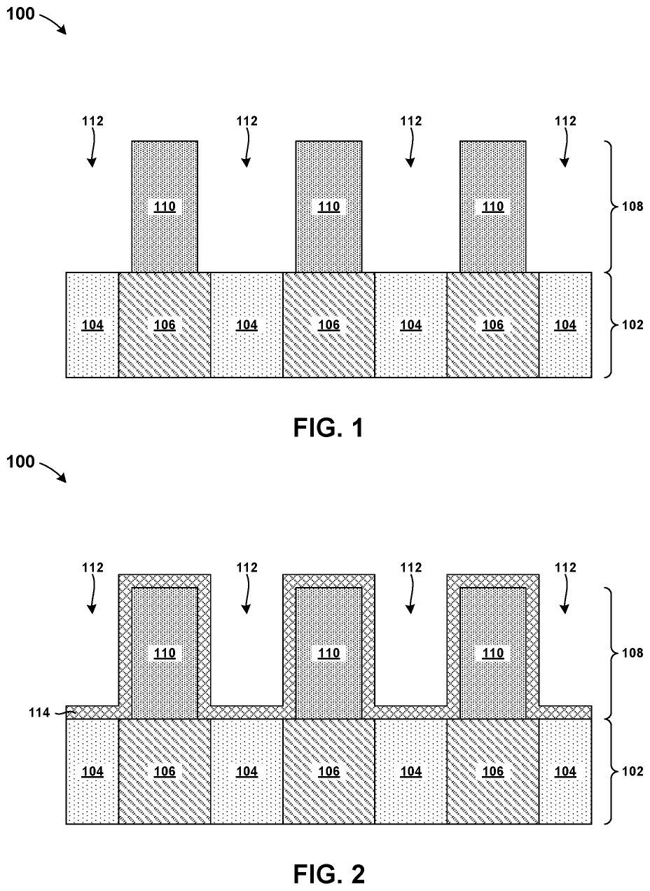

The present invention generally relates to semiconductor structures, and more particularly to a trench liner fuse structure. More specifically, the trench liner fuse structures disclosed herein are arranged between two trench liners. Doing so enables fuse integration in tight spaces. Exemplary embodiments of the trench liner fuse structures are described in detail below by referring to the accompanying drawings in FIGS. 1 to 20. Those skilled in the art will readily appreciate that the detailed description given herein with respect to these figures is for explanatory purposes as the invention extends beyond these limited embodiments.

Referring now to FIG. 1 a demonstrative illustration of a structure 100 is shown during an intermediate step of a method of fabricating a fuse structure according to an embodiment of the invention. More specifically, as disclosed herein, the method may begin with forming a metal level 102.

According to embodiments of the present invention, the metal level 102 can be any typical back-end-of-line level and includes a first dielectric layer 104 having a network of conductive lines 106 formed therein.

The first dielectric layer 104 may be composed of, for example, silicon oxide (SiOₓ), undoped silicate glass (USG), fluorosilicate glass (FSG), borophosphosilicate glass (BPSG), a spin-on low-K dielectric layer, a chemical vapor deposition (CVD) low-K dielectric layer or any combination thereof. As indicated above, the term “low-K” as used herein refers to a material having a relative dielectric constant k which is lower than that of silicon dioxide. In an embodiment, the first dielectric layer 104 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

The conductive lines 106 form “wiring” or electrical connections to underlying transistors. The conductive lines 106 may alternatively be referred to as metal lines, traces, or metal traces. The conductive lines 106 of the metal level 102 may be formed using typical damascene techniques or other known subtractive etching techniques.

The conductive lines 106 may include cobalt, ruthenium, aluminum, tungsten or other platinum group metals. As is typical of most semiconductor interconnect structures, such as the conductive lines 106, one or more liners or barrier layers (note shown) may be first deposited within openings prior to depositing the primary conductive material. Typically, liners may include, for example, tantalum nitride (TaN), followed by an additional layer including tantalum (Ta). Alternatively, liners may include cobalt (Co) or ruthenium (Ru) either alone or in combination with any other suitable liner.

As such, the conductive lines 106 may generally have common line dimensions and common line spacing that which is commensurate with current lithography limitations. In an embodiment, for example, the width or critical dimension of the conductive lines 106 can range from approximately 8 nm to approximately 10 nm; however, other width lesser than 10 nm and greater than 15 nm are explicitly contemplated. Additionally, according to at least an embodiment, the conductive lines 106 are spaced with a common line pitch, such as, for example, approximately 30 nm or less.

The pitch and position of the conductive lines 106 is specifically chosen to facilitate the embodiments disclosed herein. Specifically, for example, two conductive lines 106 are positioned adjacent to one another to facilitate formation of the fuse structure described herein.

After deposition, a planarization technique such as, for example, chemical mechanical planarization (CMP) and/or grinding is applied. The planarization technique removes excess material and continues polishing until the uppermost surfaces of the conductive lines 106 are flush, or substantially flush, with an uppermost surface of the first dielectric layer 104.

Next, a via level 108 is formed above the metal level 102 according to known techniques. First, a second dielectric layer 110 is blanket deposited across the structure 100. More specifically, the second dielectric layer 110 is deposited directly on top of the first dielectric layer 104 and the conductive lines 106, as illustrated. In at least one embodiment, the second dielectric layer 110 and the first dielectric layer 104 are made from identical materials. In other embodiment, the second dielectric layer 110 is made a different material than the first dielectric layer 104.

Next, trenches 112 are formed in the second dielectric layer 110. For example, a mask (not shown) is first deposited and patterned to expose portions of the metal level 102. Next, known etching techniques are used to remove portions of the second dielectric layer 110 selective to the mask. In doing so, topmost surfaces of the first dielectric layer 104 and the conductive lines 106 will be exposed, as illustrated. For example, in at least an embodiment, a directional dry etching technique, such as reactive ion etching, is used to etch or remove portions of the second dielectric layer 110. The trenches 112 are generally aligned between underlying conductive lines 106; however, perfect alignment is not required.

In all cases, it is critical that at least a small portion of two adjacent conductive lines (106) is exposed within the trenches 112. Said differently, at least a small portion of one conductive line (106) is exposed on one side of each trench 112 and at least a small portion of an adjacent conductive line (106) is exposed on an opposite side of each trench 112, also as illustrated. At this step, etching of the trenches 112 is generally selective to the metal level 102, including both the first dielectric layer 104 and the conductive lines 106. As such, exposed portions of the conductive lines 106 will be generally limited to top surfaces, as illustrated.

According to at least one embodiment, the trenches 112 are arranged run parallel to the conductive lines 106, as illustrated. In other embodiments, the trenches 112 may be arranged perpendicular to the conductive lines 106.

Critical to the present invention, the pitch and position of the trenches 112 is specifically chosen to facilitate the embodiments disclosed herein. Specifically, for example, a single trench 112 is intentionally positioned between two adjacent underlying conductive lines 106 to facilitate subsequent formation of the fuse structure disclosed herein. Moreover, although perfect alignment between the trenches 112 and the conductive lines 106 is not required, some alignment is necessary to realize the fuse structures disclosed herein. Finally, embodiments of the present invention are specifically contemplated when a distance between adjacent conductive lines 106 and the trenches 112 is sub-lithographic.

Referring now to FIG. 2, the structure 100 is shown after forming a conductive liner 114 in accordance with an embodiment of the present invention. In doing so, the conductive liner 114 is conformally deposited across exposed surfaces of the structure 100 and within the trenches 112. By “conformal” it is meant that a material layer has a continuous thickness. For example, a continuous thickness generally means a first thickness as measured from a bottom surface to a topmost surface that is the same as a second thickness as measured from an inner sidewall surface to an outer sidewall surface. In another embodiment, the conductive liner 114 may be a non-conformal layer.

The conductive liner 114 can be any conductive material suitable for conformal deposition. In the present embodiment, the conductive liner 114 may include one or more conformal metal layers, such as, for example, ruthenium, aluminum, tungsten, tantalum, tantalum nitride, titanium, titanium nitride, or some combination thereof. The conductive liner 114 can be formed by any suitable deposition technique including, for example, atomic layer deposition or other suitable conformal deposition techniques. In general, the conductive liner 114 should be thick enough to provide the requisite conductive path for the fuse structures described herein. In an embodiment, the conductive liner 114 can have a thickness in ranging from approximately 1 nm to approximately 10 nm. Other thicknesses that are lesser than, or greater than, the aforementioned thickness range can also be employed for the conductive liner 114. Critical to the present invention, the conductive liner 114 makes direct contact with two adjacent conductive lines 106, as illustrated.

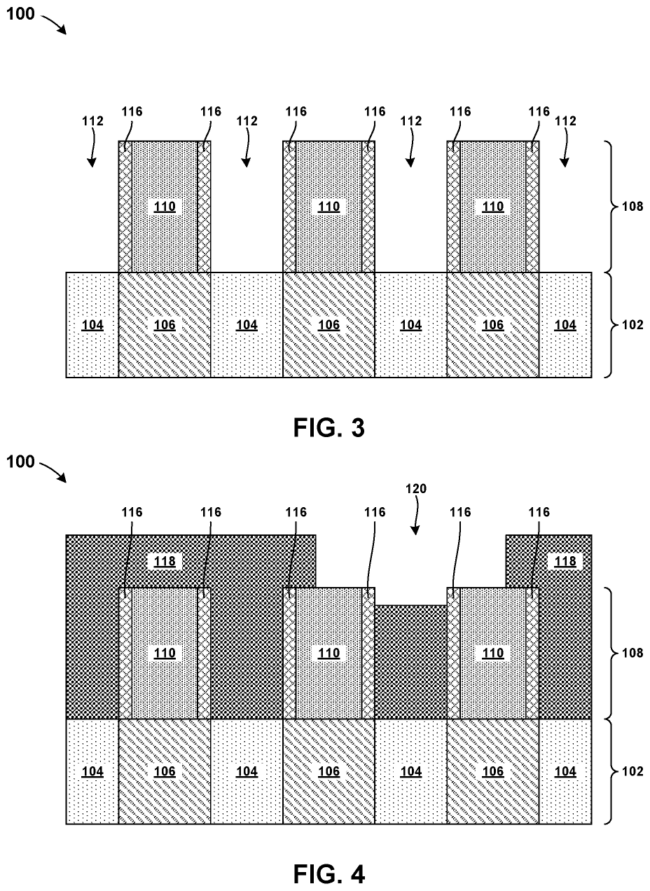

Referring now to FIG. 3, the structure 100 is shown after forming metal pillars 116 in accordance with an embodiment of the present invention. Specifically, the metal pillars 116 are formed by using an anisotropic etch to remove portions of the conductive liner 114 from the horizontal surfaces of the structure 100 while leaving portions on the sidewalls of the trenches 112, according to known techniques. The remaining portions of the conductive liner 114 become the metal pillars 116, as illustrated.

Referring now to FIG. 4, the structure 100 is shown after forming a third dielectric layer 118 and forming openings 120 in accordance with an embodiment of the present invention. First, the third dielectric layer 118 is blanket deposited across the structure 100. More specifically, the third dielectric layer 118 is deposited within the trenches 112 and directly on top of the second dielectric layer 110, the metal pillars 116 and the conductive lines 106, as illustrated. In at least one embodiment, the third dielectric layer 118 and second dielectric layer 110 are made from different materials. Although not critical, doing so enables etch selectivity between the two layers during subsequent processing.

Next, portions of the third dielectric layer 118 are etched or removed to create the openings 120 according to known techniques. In general, each of the openings 120 is located and arranged specifically to expose two adjacent metal pillars 116 separated by a portion of the third dielectric layer 118, as illustrated. Said differently, each of the openings 120 is located and arranged specifically to expose two adjacent metal pillars 116 each above and directly contacting two different conductive lines 106, as illustrated.

In at least an embodiment, for example, reactive ion etching (RIE) may be used to create the openings 120. Recessing or etching may continue until uppermost and sidewall surfaces of the two target metal pillars 116. In doing so, uppermost surfaces of portions of the second dielectric layer 110 will also be exposed, as illustrated. As such, etching should be selective to the second dielectric layer 110 and the metal pillars 116.

Finally, although only one opening 120 is depicted in the figures, multiple openings 120 across the structure 100 are explicitly contemplated. Each of the multiple openings 120 would correspond with design and placement of the fuse structures described herein.

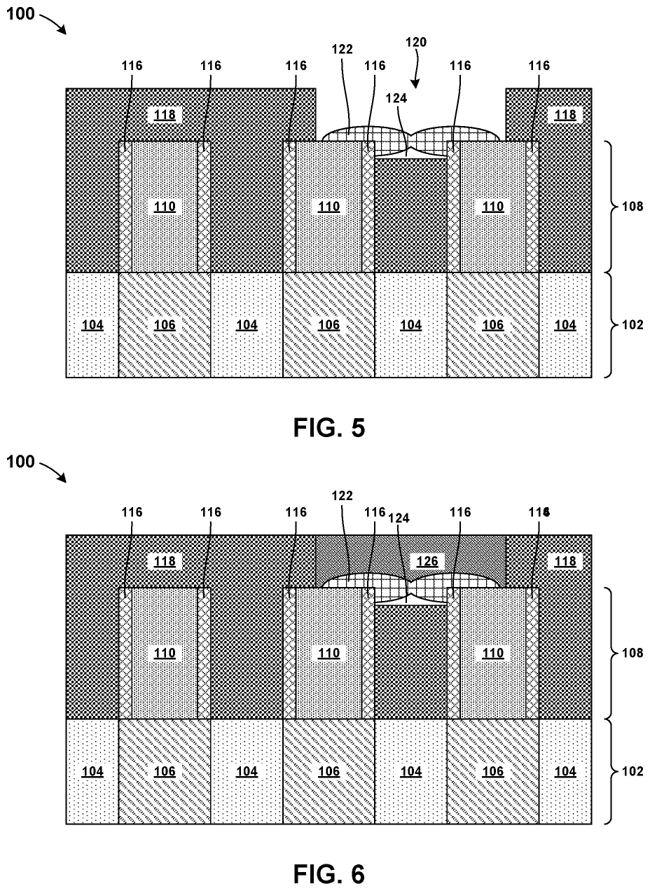

Referring now to FIG. 5, the structure 100 is shown after forming a conductive link 122 in accordance with an embodiment of the present invention. Specifically, the conductive link 122 is formed by selectively depositing a metal according to known techniques. For example, the metal is deposited on exposed surfaces of the metal pillars 116 selective to surrounding dielectrics. Stated differently, metals are deposited on the metal pillars 116 only and not on the surrounding dielectrics. According to embodiments of the present embodiment, the metal of the conductive link 122 will deposit directly on exposed top surfaces and exposed sidewalls of the metal pillars 116, as illustrated. As a result of the chosen selective deposition technique, the conductive link 122 will have a unique shape which is different from shapes resulting from other possible deposition techniques. For example, the conductive link 122 may be substantially symmetrical about a vertical centerline. Furthermore, a thickness of the conductive link 122 is inversely proportional to a distance measured from each of the metal pillars 116. For example, as the distance measured from one of the metal pillars 116 increases, the vertical thickness of the conductive link 122 decreases. As such, the vertical thickness of the conductive link 122 is the smallest at the centerline between both of the metal pillars 116, as depicted in the figures. Similarly, the vertical thickness of the conductive link 122 is the largest at, or nearest, each of the metal pillars 116, as depicted in the figures. Additionally, unique to the present invention, formation of the conductive link 122 will create an air gap 124 immediately beneath the conductive link 122. The airgap is primarily a byproduct, and thus signature, of the disclose fabrication method.

Known CVD or PECVD or ALD or PEALD techniques may be used to selectively deposit metals, such as, for example, ruthenium, aluminum, tungsten, tantalum, tantalum nitride, titanium, titanium nitride, or combinations thereof. Furthermore, the metal may be chosen based specifically on the underlying material on which it is being deposited. As such, the metal for selective deposition should be selected based on the material of the metal pillars 116. Doing so will ensure adequate adhesion between the conductive link 122 and the metal pillars 116. Other characteristics, such as resistivity and melting point, may also be considered when selecting an appropriate metal.

Referring now to FIG. 6, the structure 100 is shown after forming a fourth dielectric layer 126 in accordance with an embodiment of the present invention. The fourth dielectric layer 126 is blanket deposited across the structure 100. More specifically, the fourth dielectric layer 126 is deposited within the opening 120 and covering the conductive link 122, as illustrated. In at least one embodiment, the fourth dielectric layer 126 and the third dielectric layer 118 are made from identical materials. In other embodiments, the fourth dielectric layer 126 is made from a different material than the third dielectric layer 118.

After deposition, a planarization technique such as, for example, chemical mechanical planarization (CMP) and/or grinding is applied. The planarization technique removes excess material and continues polishing until the uppermost surfaces of the fourth dielectric layer 126 are flush, or substantially flush, with an uppermost surface of the third dielectric layer 118.

As illustrated in FIG. 6, the fuse structure represented by the structure 100 has some distinctive notable features. For example, the structure 100 has a conductive link 122 made from two selectively grown metal elements touching each other at the tip with the air gap 124 immediately below the fuse structure. The conductive link 122 has a variable thickness along its length (thinnest at the center when the two selectively grown metal elements meet). Thickness of the conductive link 122 can also vary along it's width. Length and thickness of the conductive link 122 are dependent on a distance between two adjacent conductive lines 106 which function as two electrodes.

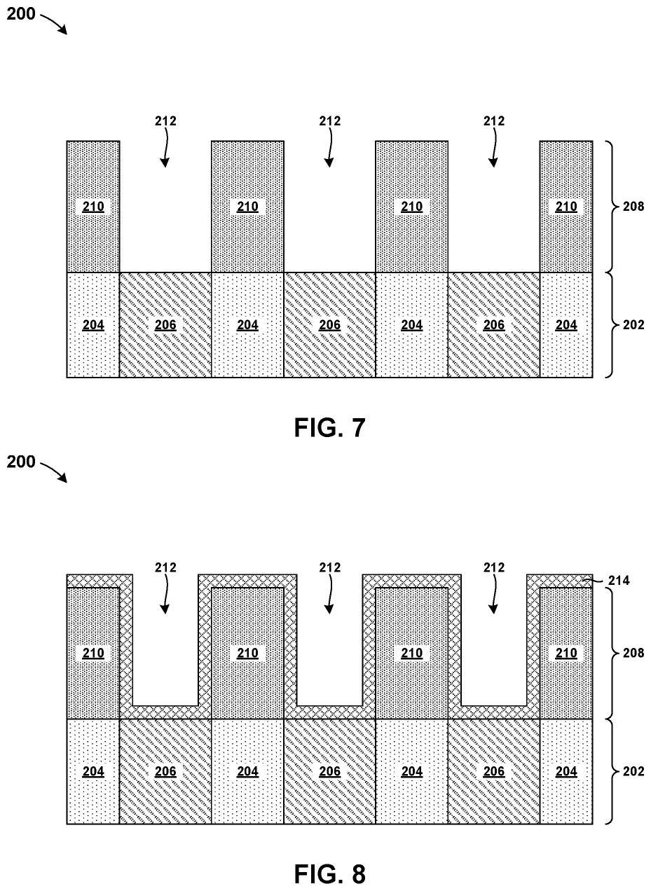

Referring now to FIG. 7 a demonstrative illustration of a structure 200 is shown during an intermediate step of a method of fabricating a fuse structure according to an alternative embodiment of the invention. More specifically, as disclosed herein, the method may begin with forming a metal level 202.

According to embodiments of the present invention, the metal level 202 can be any typical back-end-of-line level and includes a first dielectric layer 204 having a network of conductive lines 206 formed therein.

The first dielectric layer 204 may be composed of, for example, silicon oxide (SiOₓ), undoped silicate glass (USG), fluorosilicate glass (FSG), borophosphosilicate glass (BPSG), a spin-on low-K dielectric layer, a chemical vapor deposition (CVD) low-K dielectric layer or any combination thereof. As indicated above, the term “low-K” as used herein refers to a material having a relative dielectric constant k which is lower than that of silicon dioxide. In an embodiment, the first dielectric layer 204 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

The conductive lines 206 form “wiring” or electrical connections to underlying transistors. The conductive lines 206 may alternatively be referred to as metal lines, traces, or metal traces. The conductive lines 206 of the metal level 202 may be formed using typical damascene techniques or other known subtractive etching techniques.

The conductive lines 206 may include cobalt, ruthenium, aluminum, tungsten or other platinum group metals. As is typical of most semiconductor interconnect structures, such as the conductive lines 206, one or more liners or barrier layers (note shown) may be first deposited within openings prior to depositing the primary conductive material. Typically, liners may include, for example, tantalum nitride (TaN), followed by an additional layer including tantalum (Ta). Alternatively, liners may include cobalt (Co) or ruthenium (Ru) either alone or in combination with any other suitable liner.

As such, the conductive lines 206 may generally have common line dimensions and common line spacing that which is commensurate with current lithography limitations. In an embodiment, for example, the width or critical dimension of the conductive lines 206 can range from approximately 8 nm to approximately 10 nm; however, other width lesser than 10 nm and greater than 15 nm are explicitly contemplated. Additionally, according to at least an embodiment, the conductive lines 206 are spaced with a common line pitch, such as, for example, approximately 30 nm or less.

The pitch and position of the conductive lines 206 is specifically chosen to facilitate the embodiments disclosed herein. Specifically, for example, two conductive lines 206 are positioned adjacent to one another to facilitate formation of the fuse structure described herein.

After deposition, a planarization technique such as, for example, chemical mechanical planarization (CMP) and/or grinding is applied. The planarization technique removes excess material and continues polishing until the uppermost surfaces of the conductive lines 206 are flush, or substantially flush, with an uppermost surface of the first dielectric layer 204.

Next, a via level 208 is formed above the metal level 202 according to known techniques. First, a second dielectric layer 210 is blanket deposited across the structure 200. Moe specifically, the second dielectric layer 210 is deposited directly on top of the first dielectric layer 204 and the conductive lines 206, as illustrated. In at least one embodiment, the second dielectric layer 210 and the first dielectric layer 204 are made from identical materials. In other embodiment, the second dielectric layer 210 is made a different material than the first dielectric layer 204.

Next, trenches 212 are formed in the second dielectric layer 210. For example, a mask (not shown) is first deposited and patterned to expose portions of the metal level 202. Next, known etching techniques are used to remove portions of the second dielectric layer 210 selective to the mask. In doing so, topmost surfaces of the conductive lines 206 will be exposed, as illustrated. For example, in at least an embodiment, a directional dry etching technique, such as reactive ion etching, is used to etch or remove portions of the second dielectric layer 210. Unlike the structure 100, the trenches 212 of the structure 200 are generally aligned with the conductive lines 206; however, perfect alignment is not required.

In all cases, it is critical that topmost surfaces of the conductive lines (206) are exposed within the trenches 212. At this step, etching of the trenches 212 is generally selective to the metal level 202, including both the first dielectric layer 204 and the conductive lines 206. As such, exposed portions of the conductive lines 206 will be generally limited to top surfaces, as illustrated.

According to at least one embodiment, the trenches 212 are arranged run parallel to the conductive lines 206, as illustrated. In other embodiments, the trenches 212 may be arranged perpendicular to the conductive lines 206.

Critical to the present invention, the pitch and position of the trenches 212 is specifically chosen to facilitate the embodiments disclosed herein. Specifically, for example, two trenches 212 are positioned adjacent to one another to facilitate formation of the fuse structure described herein. Although the trench spacing is similar to that of the structure 100, alignment between the trenches and the conductive lines is different between the structure 100 and the structure 200. Although perfect alignment between the trenches 212 and the conductive lines 206 is not required, some alignment is necessary to realize the fuse structures disclosed herein. Finally, embodiments of the present invention are specifically contemplated when a distance between adjacent trenches 212 is sub-lithographic.

Referring now to FIG. 8, the structure 200 is shown after forming a conductive liner 214 in accordance with an embodiment of the present invention. In doing so, the conductive liner 214 is conformally deposited across exposed surfaces of the structure 200 and within the trenches 212. By “conformal” it is meant that a material layer has a continuous thickness. For example, a continuous thickness generally means a first thickness as measured from a bottom surface to a topmost surface that is the same as a second thickness as measured from an inner sidewall surface to an outer sidewall surface. In another embodiment, the conductive liner 214 may be a non-conformal layer.

The conductive liner 214 can be any conductive material suitable for conformal deposition. In the present embodiment, the conductive liner 214 may include one or more conformal metal layers, such as, for example, ruthenium, aluminum, tungsten, tantalum, tantalum nitride, titanium, titanium nitride, or some combination thereof. The conductive liner 214 can be formed by any suitable deposition technique including, for example, atomic layer deposition or other suitable conformal deposition techniques. In general, the conductive liner 214 should be thick enough to provide the requisite conductive path for the fuse structures described herein. In an embodiment, the conductive liner 214 can have a thickness in ranging from approximately 1 nm to approximately 10 nm. Other thicknesses that are lesser than, or greater than, the aforementioned thickness range can also be employed for the conductive liner 214. Critical to the present invention, the conductive liner 214 makes direct contact with topmost surfaces of the conductive lines 206, as illustrated.

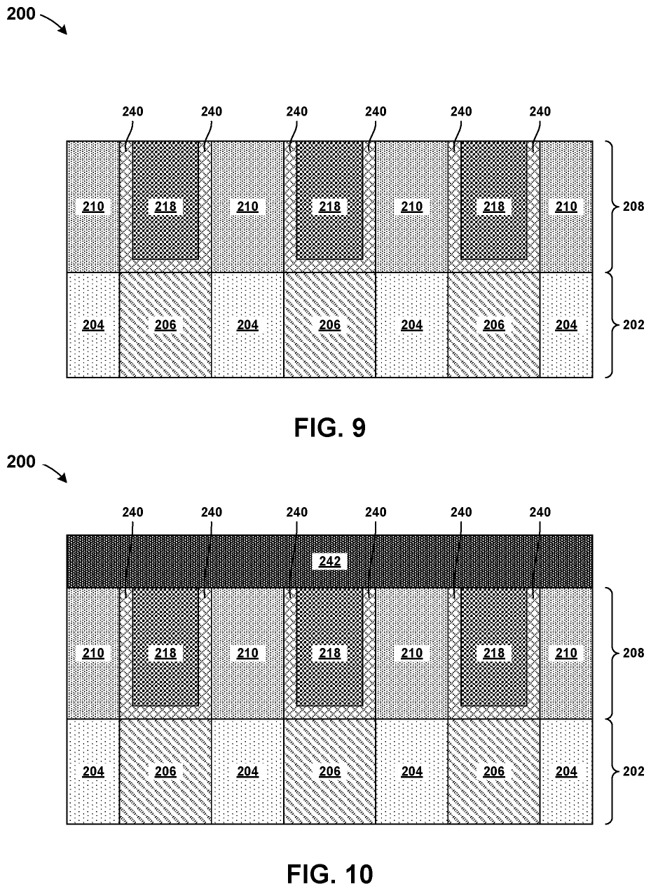

Referring now to FIG. 9, the structure 200 is shown after forming a third dielectric layer 218 and forming metal pillars 240 in accordance with an embodiment of the present invention. First, the third dielectric layer 218 is blanket deposited across the structure 200. More specifically, the third dielectric layer 218 is deposited within the trenches 212 and directly on top of the second dielectric layer 210, the conductive liner 214. In at least one embodiment, the third dielectric layer 218 and second dielectric layer 210 are made from different materials. Although not critical, doing so enables etch selectivity between the two layers during subsequent processing.

Next, the metal pillars 240 are formed by using a planarization technique such as, for example, chemical mechanical planarization (CMP) to removes excess material from topmost surfaces of the structure 200. Polishing continues until the uppermost surfaces of the second dielectric layer 210 are flush, or substantially flush, with an uppermost surface of the third dielectric layer 218.

In doing so, portions of the conductive liner 214 are removed and remaining portions form the metal pillars 240. According to the present embodiment, the metal pillars 240 immediately adjacent to one another and directly above each conductive line 206 are joined at the bottom. Further, uppermost surfaces of the metal pillars 240 are flush, or substantially flush, with uppermost surfaces of both the second dielectric layer 210 and the third dielectric layer 218 after polishing, as illustrated.

Referring now to FIG. 10, the structure 200 is shown after forming a fourth dielectric layer 242 in accordance with an embodiment of the present invention. The fourth dielectric layer 242 is blanket deposited across the structure 200. More specifically, the fourth dielectric layer 242 is deposited directly on top of the second dielectric layer 210, the third dielectric layer 218 and the metal pillars 240. In at least one embodiment, fourth dielectric layer 242 is made from different materials than either, or both, of the second dielectric layer 210 and the third dielectric layer 218. Doing so enables etch selectivity between the dielectric layers during subsequent processing.

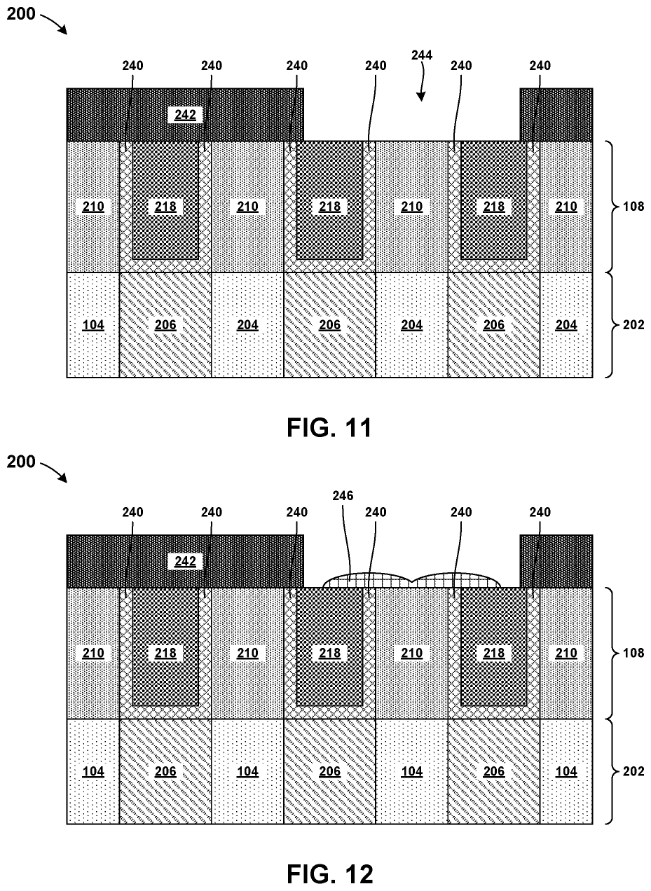

Referring now to FIG. 11, the structure 200 is shown after forming openings 244 in accordance with an embodiment of the present invention. Portions of the fourth dielectric layer 242 are etched or removed to create the openings 244 according to known techniques. In general, each of the openings 244 is located and arranged specifically to expose two adjacent metal pillars 240 separated by a portion of the second dielectric layer 210, as illustrated. Said differently, each of the openings 244 is located and arranged specifically to expose two adjacent metal pillars 240 each above and directly contacting two different conductive lines 206, as illustrated.

In at least an embodiment, for example, reactive ion etching (RIE) may be used to create the openings 244. Recessing or etching may continue until at least uppermost surfaces of the two target metal pillars 240. In doing so, portions of uppermost surfaces of portions of the second dielectric layer 210 and the third dielectric layer 218 will also be exposed, as illustrated. As such, etching should be selective to the second dielectric layer 210, the third dielectric layer 218, and the metal pillars 240.

Finally, although only one opening 244 is depicted in the figures, multiple openings 244 across the structure 200 are explicitly contemplated. Each of the multiple openings 244 would correspond with design and placement of the fuse structures described herein.

Referring now to FIG. 12, the structure 200 is shown after forming conductive link 246 in accordance with an embodiment of the present invention. Specifically, the conductive link 246 is formed by selectively depositing a metal according to known techniques. For example, the metal is deposited on exposed surfaces of the metal pillars 240 selective to surrounding dielectrics. Stated differently, metals are deposited on the metal pillars 240 only and not on the surrounding dielectrics. According to embodiments of the present embodiment, the metal of the conductive link 246 will deposit directly on exposed top surfaces of the metal pillars 240, as illustrated. As a result of the chosen selective deposition technique, the conductive link 246 will have a unique shape which is different from shapes resulting from other possible deposition techniques. For example, the conductive link 246 may be substantially symmetrical about a vertical centerline. Furthermore, a thickness of the conductive link 246 is inversely proportional to a distance measured from each of the metal pillars 240. For example, as the distance measured from one of the metal pillars 240 increases, the vertical thickness of the conductive link 246 decreases. As such, the vertical thickness of the conductive link 246 is the smallest at the centerline between both of the metal pillars 240, as depicted in the figures. Similarly, the vertical thickness of the conductive link 246 is the largest at, or nearest, each of the metal pillars 240, as depicted in the figures.

Known CVD or PECVD or ALD or PEALD techniques may be used to selectively deposit metals, such as, for example, ruthenium, aluminum, tungsten, tantalum, tantalum nitride, titanium, titanium nitride, or combinations thereof. Furthermore, the metal may be chosen based specifically on the underlying material on which it is being deposited. As such, the metal for selective deposition should be selected based on the material of the metal pillars 240. Doing so will ensure adequate adhesion between the conductive link 246 and the metal pillars 240. Other characteristics, such as resistivity and melting point, may also be considered when selecting an appropriate metal.

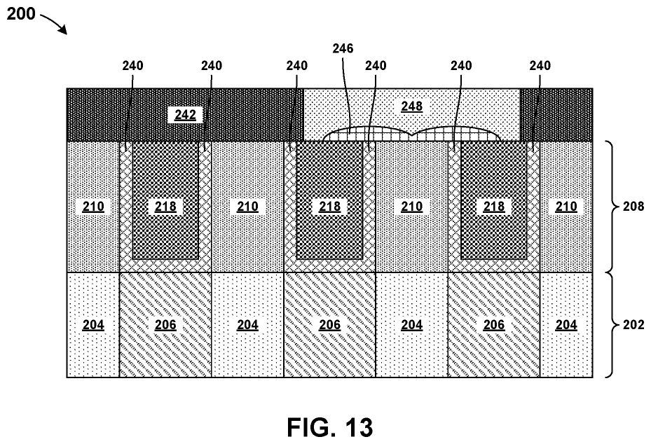

Referring now to FIG. 13, the structure 200 is shown after forming a fifth dielectric layer 248 in accordance with an embodiment of the present invention. The fifth dielectric layer 248 is blanket deposited across the structure 200. More specifically, the fifth dielectric layer 248 is deposited within the opening 244 and covering the conductive link 246, as illustrated. In at least one embodiment, the fifth dielectric layer 248 and the fourth dielectric layer 242are made from identical materials. In other embodiments, the fifth dielectric layer 248 and the fourth dielectric layer 242 are made from a different material than the third dielectric layer 218.

After deposition, a planarization technique such as, for example, chemical mechanical planarization (CMP) and/or grinding is applied. The planarization technique removes excess material and continues polishing until the uppermost surfaces of the fifth dielectric layer 248 are flush, or substantially flush, with uppermost surfaces of the fourth dielectric layer 242.

As illustrated in FIG. 13, the fuse structure represented by the structure 200 has some distinctive notable features. For example, the structure 220 has the conductive link 246 from two selectively grown metal elements touching each other at the. The conductive link 246 has a variable thickness along its length (thinnest at the center when the two selectively grown metal elements meet). Thickness of the conductive link 246 can also vary along it's width. Length and thickness of the conductive link 246 are dependent on a distance between two adjacent conductive lines 206 which function as two electrodes.

With continued reference to FIG. 13, according to an embodiment the fuse structures represented by the structure 100 include a first conductive line (106) and a second conductive line (106), a first metal pillar (116) extending vertically from a top surface of the first conductive line and a second metal pillar (116) extending vertically from a top surface of the second conductive line, a conductive link (122) electrically connecting a top surface of the first metal pillar with a top surface of the second metal pillar, where both the first conductive line and the second conductive line are a different material than both the first metal pillar and the second metal pillar, and where both the first metal pillar and the second metal pillar are a different metal than the conductive link.

With continued reference to FIG. 13, and according to an embodiment, both the first conductive line (106) and the second conductive line (106) are a different material than the conductive link (122).

With continued reference to FIG. 13, and according to an embodiment, a lateral width of each of the first conductive line (106) and the second conductive line (106) is at least 80% greater than a lateral width of each of the first metal pillar (116) and the second metal pillar (116).

With continued reference to FIG. 13, and according to an embodiment, a lateral distance between the first conductive line (106) and the second conductive (106) line substantially equal to a lateral distance between the first metal pillar (116) and the second metal pillar (116).

With continued reference to FIG. 13, and according to an embodiment, a lateral distance between the first conductive line (106) and the second conductive line (106) less than a lateral distance between the first metal pillar (116) and the second metal pillar (116).

With continued reference to FIG. 13, and according to an embodiment, both the first metal pillar (116) and the second metal pillar (116) are made from a metal having a higher electrical resistivity than a metal of the conductive link (122).

With continued reference to FIG. 13, and according to an embodiment, opposite sidewalls of the first metal pillar (116) directly contact different dielectric materials.

With continued reference to FIG. 13, according to an embodiment the fuse structures represented by the structure 100 include a first metal line (106) and a second metal line (106), a first metal pillar (116) extending vertically from a top surface of the first metal line (106) and a second metal pillar (116) extending vertically from a top surface of the second metal line (106), a conductive link (122) electrically connecting a top surface of the first metal pillar to a top surface of the second metal pillar, where both the first metal line and the second metal line are a different metal than both the first metal pillar and the second metal pillar, where both the first metal pillar and the second metal pillar are a different metal than the conductive link, and where the conductive link directly contacts a sidewall of the first metal pillar and a sidewall of the second metal pillar.

With continued reference to FIG. 13, according to an embodiment the fuse structures represented by the structure 100 include a first metal via (106) and a second metal via (106), a first metal pillar (116) extending vertically from a top surface of the first metal via (106) and a second metal pillar (116) extending vertically from a top surface of the second metal via (106), where both the first metal via and the second metal via are a different metal than both the first metal pillar and the second metal pillar; and a conductive link (122) electrically connecting the first metal pillar to the second metal pillar, wherein both the first metal pillar and the second metal pillar are a different metal than the conductive link, and where the conductive link comprises a first cross-sectional dimension and a second cross-sectional dimension, where the first cross-sectional dimension is smaller than the second cross-sectional dimension, and where the first cross-sectional dimension is approximately located at a mid-point between the first metal pillar and the second metal pillar.

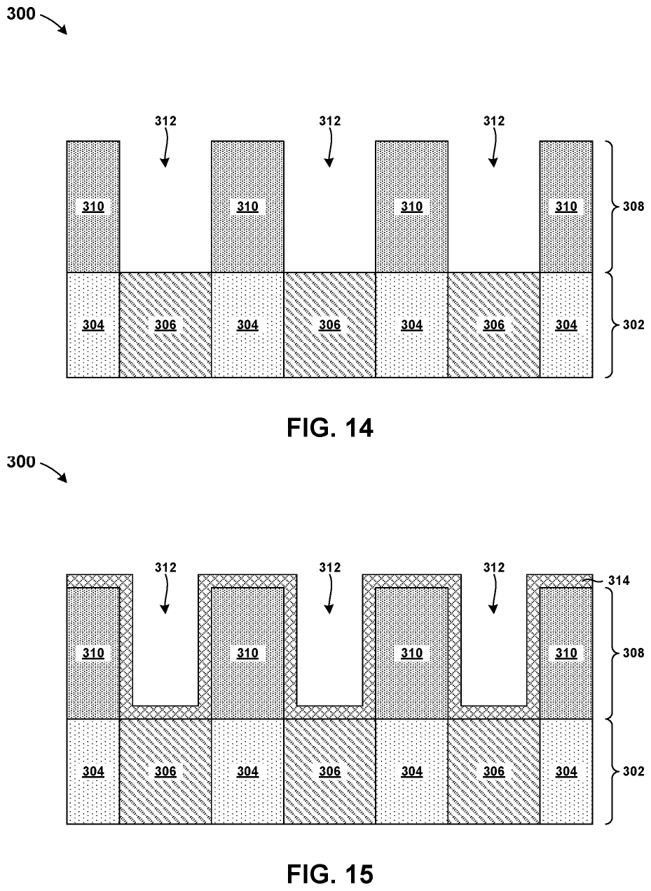

Referring now to FIG. 14 a demonstrative illustration of a structure 300 is shown during an intermediate step of a method of fabricating a fuse structure according to an alternative embodiment of the invention. More specifically, as disclosed herein, the method may begin with forming a metal level 302.

According to embodiments of the present invention, the metal level 302 can be any typical back-end-of-line level and includes a first dielectric layer 304 having a network of conductive lines 306 formed therein.

The first dielectric layer 304 may be composed of, for example, silicon oxide (SiOₓ), undoped silicate glass (USG), fluorosilicate glass (FSG), borophosphosilicate glass (BPSG), a spin-on low-K dielectric layer, a chemical vapor deposition (CVD) low-K dielectric layer or any combination thereof. As indicated above, the term “low-K” as used herein refers to a material having a relative dielectric constant k which is lower than that of silicon dioxide. In an embodiment, the first dielectric layer 304 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

The conductive lines 306 form “wiring” or electrical connections to underlying transistors. The conductive lines 306 may alternatively be referred to as metal lines, traces, or metal traces. The conductive lines 306 of the metal level 302 may be formed using typical damascene techniques or other known subtractive etching techniques.

The conductive lines 306 may include cobalt, ruthenium, aluminum, tungsten or other platinum group metals. As is typical of most semiconductor interconnect structures, such as the conductive lines 306, one or more liners or barrier layers (note shown) may be first deposited within openings prior to depositing the primary conductive material. Typically, liners may include, for example, tantalum nitride (TaN), followed by an additional layer including tantalum (Ta). Alternatively, liners may include cobalt (Co) or ruthenium (Ru) either alone or in combination with any other suitable liner.

As such, the conductive lines 306 may generally have common line dimensions and common line spacing that which is commensurate with current lithography limitations. In an embodiment, for example, the width or critical dimension of the conductive lines 306 can range from approximately 8 nm to approximately 10 nm; however, other width lesser than 10 nm and greater than 15 nm are explicitly contemplated. Additionally, according to at least an embodiment, the conductive lines 306 are spaced with a common line pitch, such as, for example, approximately 30 nm or less.

The pitch and position of the conductive lines 306 is specifically chosen to facilitate the embodiments disclosed herein. Specifically, for example, two conductive lines 306 are positioned adjacent to one another to facilitate formation of the fuse structure described herein.

After deposition, a planarization technique such as, for example, chemical mechanical planarization (CMP) and/or grinding is applied. The planarization technique removes excess material and continues polishing until the uppermost surfaces of the conductive lines 306 are flush, or substantially flush, with an uppermost surface of the first dielectric layer 304.

Next, a via level 308 is formed above the metal level 302 according to known techniques. First, a second dielectric layer 310 is blanket deposited across the structure 300. Moe specifically, the second dielectric layer 310 is deposited directly on top of the first dielectric layer 304 and the conductive lines 306, as illustrated. In at least one embodiment, the second dielectric layer 310 and the first dielectric layer 304 are made from identical materials. In other embodiment, the second dielectric layer 310 is made a different material than the first dielectric layer 304.

Next, trenches 312 are formed in the second dielectric layer 310. For example, a mask (not shown) is first deposited and patterned to expose portions of the metal level 302. Next, known etching techniques are used to remove portions of the second dielectric layer 310 selective to the mask. In doing so, topmost surfaces of the conductive lines 306 will be exposed, as illustrated. For example, in at least an embodiment, a directional dry etching technique, such as reactive ion etching, is used to etch or remove portions of the second dielectric layer 310. Like the structure 200, the trenches 312 of the structure 300 are generally aligned with the conductive lines 306; however, perfect alignment is not required.

In all cases, it is critical that topmost surfaces of the conductive lines (306) are exposed within the trenches 312. At this step, etching of the trenches 312 is generally selective to the metal level 302, including both the first dielectric layer 304 and the conductive lines 306. As such, exposed portions of the conductive lines 306 will be generally limited to top surfaces, as illustrated.

According to at least one embodiment, the trenches 312 are arranged run parallel to the conductive lines 306, as illustrated. In other embodiments, the trenches 312 may be arranged perpendicular to the conductive lines 306.

Critical to the present invention, the pitch and position of the trenches 312 is specifically chosen to facilitate the embodiments disclosed herein. Specifically, for example, two trenches 312 are positioned adjacent to one another to facilitate formation of the fuse structure described herein. Although the trench spacing is similar to that of the structure 100, alignment between the trenches and the conductive lines is different between the structure 100 and the structure 300. Although perfect alignment between the trenches 312 and the conductive lines 306 is not required, some alignment is necessary to realize the fuse structures disclosed herein. Finally, embodiments of the present invention are specifically contemplated when a distance between adjacent trenches 312 is sub-lithographic.

Referring now to FIG. 15, the structure 300 is shown after forming a conductive liner 314 in accordance with an embodiment of the present invention. In doing so, the conductive liner 314 is conformally deposited across exposed surfaces of the structure 300 and within the trenches 312. By “conformal” it is meant that a material layer has a continuous thickness. For example, a continuous thickness generally means a first thickness as measured from a bottom surface to a topmost surface that is the same as a second thickness as measured from an inner sidewall surface to an outer sidewall surface. In another embodiment, the conductive liner 314 may be a non-conformal layer.

The conductive liner 314 can be any conductive material suitable for conformal deposition. In the present embodiment, the conductive liner 314 may include one or more conformal metal layers, such as, for example, ruthenium, aluminum, tungsten, tantalum, tantalum nitride, titanium, titanium nitride, or some combination thereof. The conductive liner 314 can be formed by any suitable deposition technique including, for example, atomic layer deposition or other suitable conformal deposition techniques. In general, the conductive liner 314 should be thick enough to provide the requisite conductive path for the fuse structures described herein. In an embodiment, the conductive liner 314 can have a thickness in ranging from approximately 1 nm to approximately 10 nm. Other thicknesses that are lesser than, or greater than, the aforementioned thickness range can also be employed for the conductive liner 314. Critical to the present invention, the conductive liner 314 makes direct contact with topmost surfaces of the conductive lines 306, as illustrated.

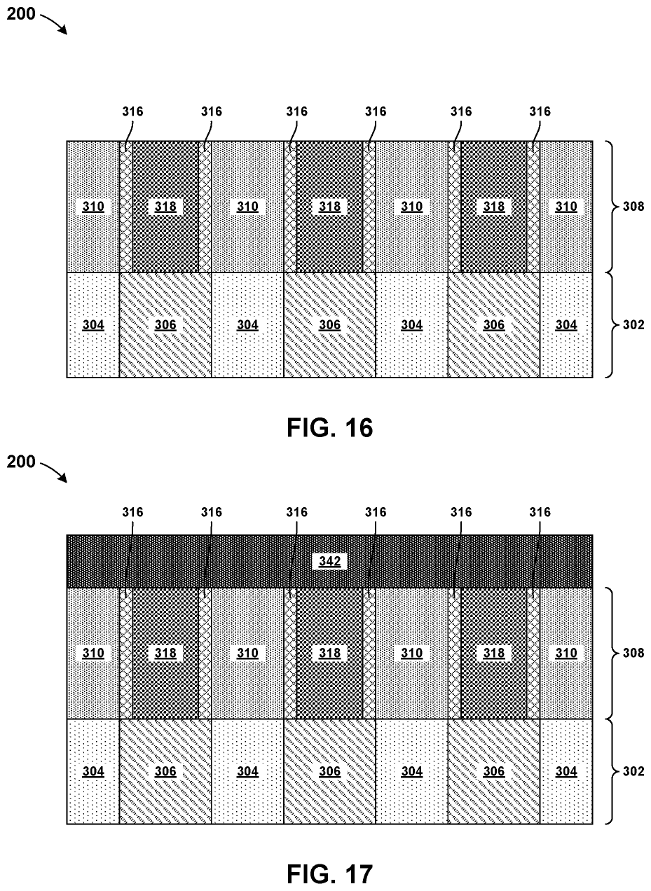

Referring now to FIG. 16, the structure 300 is shown after forming metal pillars 316 and depositing a third dielectric layer 318 in accordance with an embodiment of the present invention. First, the metal pillars 316 are formed by using an anisotropic etch to remove portions of the conductive liner 314 from the horizontal surfaces of the structure 300 while leaving portions on the sidewalls of the trenches 312, according to known techniques. The remaining portions of the conductive liner 314 become the metal pillars 316, as illustrated.

Next, the third dielectric layer 318 is blanket deposited across the structure 300. More specifically, the third dielectric layer 318 is deposited within the trenches 312 and directly on top of the second dielectric layer 310, the metal pillars 316, and the conductive lines 306. In at least one embodiment, the third dielectric layer 318 and second dielectric layer 310 are made from different materials. Although not critical, doing so enables etch selectivity between the two layers during subsequent processing.

Next, a planarization technique such as, for example, chemical mechanical planarization (CMP) to removes excess material from topmost surfaces of the structure 300. Polishing continues until the uppermost surfaces of the third dielectric layer 318 are flush, or substantially flush, with an uppermost surface of the second dielectric layer 310 and the metal pillars 316.

In doing so, portions of the conductive liner 314 are removed and remaining portions form the metal pillars 316. According to the present embodiment, the metal pillars 316 immediately adjacent to one another and directly above each conductive line 306 are joined at the bottom. Further, uppermost surfaces of the metal pillars 316 are flush, or substantially flush, with uppermost surfaces of both the second dielectric layer 310 and the third dielectric layer 318 after polishing, as illustrated.

Referring now to FIG. 17, the structure 300 is shown after forming a fourth dielectric layer 342 in accordance with an embodiment of the present invention. The fourth dielectric layer 342 is blanket deposited across the structure 300. More specifically, the fourth dielectric layer 342 is deposited directly on top of the second dielectric layer 310, the third dielectric layer 318 and the metal pillars 316. In at least one embodiment, fourth dielectric layer 342 is made from different materials than either, or both, of the second dielectric layer 310 and the third dielectric layer 318. Doing so enables etch selectivity between the dielectric layers during subsequent processing.

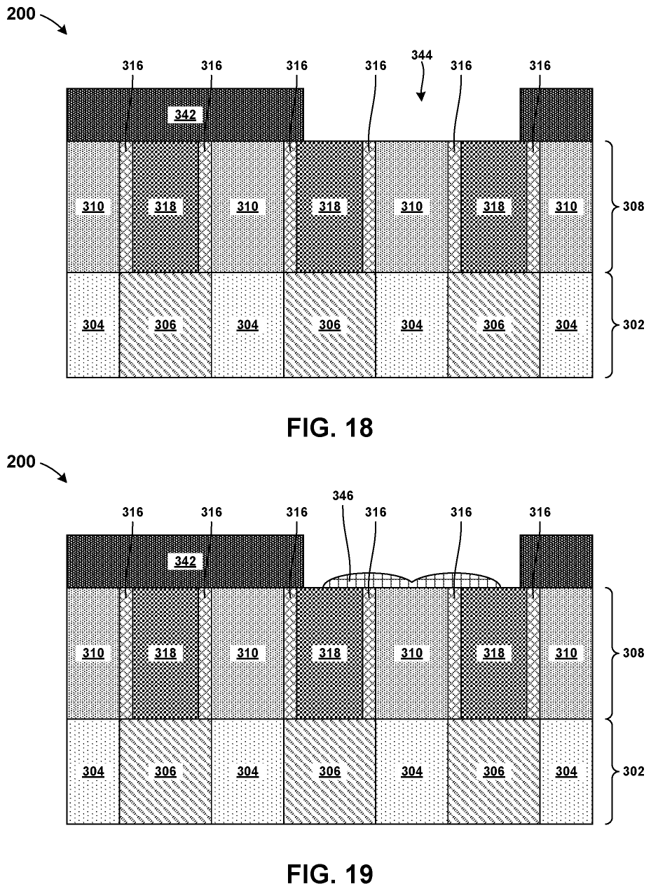

Referring now to FIG. 18, the structure 300 is shown after forming openings 344 in accordance with an embodiment of the present invention. Portions of the fourth dielectric layer 342 are etched or removed to create the openings 344 according to known techniques. In general, each of the openings 344 is located and arranged specifically to expose two adjacent metal pillars 316 separated by a portion of the second dielectric layer 310, as illustrated. Said differently, each of the openings 344 is located and arranged specifically to expose two adjacent metal pillars 316 each above and directly contacting two different conductive lines 306, as illustrated.

In at least an embodiment, for example, reactive ion etching (RIE) may be used to create the openings 344. Recessing or etching may continue until at least uppermost surfaces of the two target metal pillars 316. In doing so, portions of uppermost surfaces of portions of the second dielectric layer 310 and the third dielectric layer 318 will also be exposed, as illustrated. As such, etching should be selective to the second dielectric layer 310, the third dielectric layer 318, and the metal pillars 316.

Finally, although only one opening 344 is depicted in the figures, multiple openings 344 across the structure 300 are explicitly contemplated. Each of the multiple openings 344 would correspond with design and placement of the fuse structures described herein.

Referring now to FIG. 19, the structure 300 is shown after forming a conductive link 346 in accordance with an embodiment of the present invention. Specifically, the conductive link 346 is formed by selectively depositing a metal according to known techniques. For example, the metal is deposited on exposed surfaces of the metal pillars 316 selective to surrounding dielectrics. Stated differently, metals are deposited on the metal pillars 316 only and not on the surrounding dielectrics. According to embodiments of the present embodiment, the metal of the conductive link 346 will deposit directly on exposed top surfaces of the metal pillars 316, as illustrated. As a result of the chosen selective deposition technique, the conductive link 346 will have a unique shape which is different from shapes resulting from other possible deposition techniques. For example, the conductive link 346 may be substantially symmetrical about a vertical centerline. Furthermore, a thickness of the conductive link 346 is inversely proportional to a distance measured from each of the metal pillars 316. For example, as the distance measured from one of the metal pillars 316 increases, the vertical thickness of the conductive link 346 decreases. As such, the vertical thickness of the conductive link 346 is the smallest at the centerline between both of the metal pillars 316, as depicted in the figures. Similarly, the vertical thickness of the conductive link 346 is the largest at, or nearest, each of the metal pillars 316, as depicted in the figures.

Known CVD or PECVD or ALD or PEALD techniques may be used to selectively deposit metals, such as, for example, ruthenium, aluminum, tungsten, tantalum, tantalum nitride, titanium, titanium nitride, or combinations thereof. Furthermore, the metal may be chosen based specifically on the underlying material on which it is being deposited. As such, the metal for selective deposition should be selected based on the material of the metal pillars 316. Doing so will ensure adequate adhesion between the conductive link 346 and the metal pillars 316. Other characteristics, such as resistivity and melting point, may also be considered when selecting an appropriate metal.

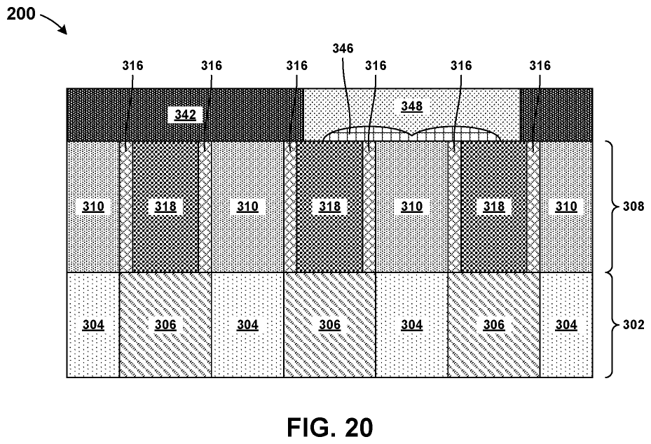

Referring now to FIG. 20, the structure 300 is shown after forming a fifth dielectric layer 348 in accordance with an embodiment of the present invention. The fifth dielectric layer 348 is blanket deposited across the structure 300. More specifically, the fifth dielectric layer 348 is deposited within the opening 344 and covering the conductive link 346, as illustrated. In at least one embodiment, the fifth dielectric layer 348 and the fourth dielectric layer 342are made from identical materials. In other embodiments, the fifth dielectric layer 348 and the fourth dielectric layer 342 are made from a different material than the third dielectric layer 318.

After deposition, a planarization technique such as, for example, chemical mechanical planarization (CMP) and/or grinding is applied. The planarization technique removes excess material and continues polishing until the uppermost surfaces of the fifth dielectric layer 348 are flush, or substantially flush, with uppermost surfaces of the fourth dielectric layer 342.

As illustrated in FIG. 20, the fuse structure represented by the structure 300 has some distinctive notable features. For example, the structure 300 has a conductive link 346 made from two selectively grown metal elements touching each other at the tip. The conductive link 346 has a variable thickness along its length (thinnest at the center when the two selectively grown metal elements meet). Thickness of the conductive link 346 can also vary along it's width. Length and thickness of the conductive link 346 are dependent on a distance between two adjacent conductive lines 106 which function as two electrodes.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A fuse structure comprising:
a first conductive line and a second conductive line;
a first metal pillar extending vertically from a top surface of the first conductive line and a second metal pillar extending vertically from a top surface of the second conductive line;
a conductive link electrically connecting a top surface of the first metal pillar with a top surface of the second metal pillar,
wherein both the first conductive line and the second conductive line are a different material than both the first metal pillar and the second metal pillar, and
wherein both the first metal pillar and the second metal pillar are a different metal than the conductive link.

2. The fuse structure according to claim 1, wherein both the first conductive line and the second conductive line are a different material than the conductive link.

3. The fuse structure according to claim 1, wherein a lateral width of each of the first conductive line and the second conductive line is at least 80% greater than a lateral width of each of the first metal pillar and the second metal pillar.

4. The fuse structure according to claim 1, wherein a lateral distance between the first conductive line and the second conductive line substantially equal to a lateral distance between the first metal pillar and the second metal pillar.

5. The fuse structure according to claim 1, wherein a lateral distance between the first conductive line and the second conductive line less than a lateral distance between the first metal pillar and the second metal pillar.

6. The fuse structure according to claim 1, wherein both the first metal pillar and the second metal pillar are made from a metal having a higher electrical resistivity than a metal of the conductive link.

7. The fuse structure according to claim 1, wherein opposite sidewalls of the first metal pillar directly contact different dielectric materials.

8. A fuse structure comprising:
a first metal line and a second metal line;
a first metal pillar extending vertically from a top surface of the first metal line and a second metal pillar extending vertically from a top surface of the second metal line;
a conductive link electrically connecting a top surface of the first metal pillar to a top surface of the second metal pillar,
wherein both the first metal line and the second metal line are a different metal than both the first metal pillar and the second metal pillar,
wherein both the first metal pillar and the second metal pillar are a different metal than the conductive link, and
wherein the conductive link directly contacts a sidewall of the first metal pillar and a sidewall of the second metal pillar.

9. The fuse structure according to claim 8, wherein both the first conductive line and the second conductive line are a different material than the conductive link.

10. The fuse structure according to claim 8, wherein a lateral width of each of the first conductive line and the second conductive line is at least 80% greater than a lateral width of each of the first metal pillar and the second metal pillar.

11. The fuse structure according to claim 8, wherein a lateral distance between the first conductive line and the second conductive line substantially equal to a lateral distance between the first metal pillar and the second metal pillar.

12. The fuse structure according to claim 8, wherein a lateral distance between the first conductive line and the second conductive line less than a lateral distance between the first metal pillar and the second metal pillar.

13. The fuse structure according to claim 8, wherein both the first metal pillar and the second metal pillar are made from a metal having a higher electrical resistivity than a metal of the conductive link.

14. The fuse structure according to claim 8, wherein opposite sidewalls of the first metal pillar directly contact different dielectric materials.

15. A fuse structure comprising:
a first metal via and a second metal via;
a first metal pillar extending vertically from a top surface of the first metal via and a second metal pillar extending vertically from a top surface of the second metal via, wherein both the first metal via and the second metal via are a different metal than both the first metal pillar and the second metal pillar; and
a conductive link electrically connecting the first metal pillar to the second metal pillar, wherein both the first metal pillar and the second metal pillar are a different metal than the conductive link, and
wherein the conductive link comprises a first cross-sectional dimension and a second cross-sectional dimension, wherein the first cross-sectional dimension is smaller than the second cross-sectional dimension, and wherein the first cross-sectional dimension is approximately located at a mid-point between the first metal pillar and the second metal pillar.

16. The fuse structure according to claim 15, wherein both the first conductive line and the second conductive line are a different material than the conductive link.

17. The fuse structure according to claim 15, wherein a lateral width of each of the first conductive line and the second conductive line is at least 80% greater than a lateral width of each of the first metal pillar and the second metal pillar.

18. The fuse structure according to claim 15, wherein a lateral distance between the first conductive line and the second conductive line substantially equal to a lateral distance between the first metal pillar and the second metal pillar.

19. The fuse structure according to claim 15, wherein a lateral distance between the first conductive line and the second conductive line less than a lateral distance between the first metal pillar and the second metal pillar.

20. The fuse structure according to claim 15, wherein both the first metal pillar and the second metal pillar are made from a metal having a higher electrical resistivity than a metal of the conductive link.
